(19) United States
(12) Patent Application Publication
(10) Pub. No.: US 2008/0099821 A1
(43) Pub. Date: May 1, 2008

(54) FLASH MEMORY DEVICE AND METHOD OF MANUFACTURING THE SAME

(75) Inventors: Jum Soo Kim, Icheon-si (KR); Seok Kiu Lee, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,675

(22) Filed: Dec. 29, 2006

(30) Foreign Application Priority Data
Oct. 31, 2006 (KR) 2006-106428

(51) Int. Cl. H01L 29/788

(52) U.S. Cl. 257/316

(57) ABSTRACT

A method of manufacturing semiconductor devices includes providing a semiconductor substrate including first active areas and isolation areas alternately arranged to be parallel to each other and second active areas connecting the first active areas to each other. A tunnel insulating layer, a charge storage layer, and an isolation mask are formed on the semiconductor substrate. The isolation mask, the charge storage layer, the tunnel insulating layer, and the semiconductor substrate are etched to form a trench on the isolation area. An isolation structure is formed on the trench. A dielectric layer, a conductive layer for a control gate, and a hard mask are sequentially formed on a structure that includes the isolation structure. The hard mask, the conductive layer for the control gate, the dielectric layer, and the charge storage layer are patterned to form drain select lines, word lines and source select lines intersecting the first active area. Junction areas are formed on the first active areas through an ion implanting process. A common source is formed on the first active areas and the second active area between adjacent source select lines.

### CROSS-REFERENCES TO RELATED APPLICATIONS

The present application claims priority to Korean patent application number 10-2006-106428, filed on Oct. 31, 2006, which is incorporated herein by reference in its entirety.

### BACKGROUND OF THE INVENTION

The present invention relates to a flash memory device and a method of manufacturing the same; and more particularly, to a flash memory device related to a cell array of a NAND flash memory device and a method of manufacturing the same.

A memory cell array of a NAND flash memory device includes a string structure. The string structure includes a drain select transistor in which a drain is connected to a bit line; a source select transistor in which a source is connected to a common source line; and a plurality memory cells connected in series between the drain select transistor and the source select transistor. A plurality of the string structures are electrically isolated and coupled in parallel. A drain select line is formed by connecting in parallel gates of the drain select transistors, a source select line is formed by connecting in parallel gates of the source select transistors, and a word line is formed by connecting in parallel gates of the memory cells. The string structures are also connected to each other in a perpendicular direction. In other words, a drain of the drain select transistor in one string structure is connected to a drain of the drain select transistor of another string structure, and a source of the source select transistor in one string structure is connected to a source of the source select transistor of another string structure.

FIG. 1 is a layout showing an active area and an isolation area in a cell area of a conventional NAND flash memory device. As described above, the string structures are connected to each other in a perpendicular direction and are isolated from each other in parallel by isolation structures in a horizontal direction. Thus, active areas 101 and isolation areas 102 are arranged in parallel lengthwise in a cell area of the NAND flash memory device.

FIG. 2 is a photograph showing where a dislocation 104 is generated on a semiconductor substrate of an active area.

Referring to FIG. 1 and FIG. 2, the isolation area 102 extends lengthwise in one direction and an isolation structure 103 is formed in the isolation area 102. Since the isolation area 102 extends lengthwise in one direction, the isolation structure 103 also extends in the same direction. Typically, in a process for forming the isolation structure 103, a trench is filled with insulative material. Thus, the process causes stress to be exerted on the active area 101 of the semiconductor substrate. When the isolation structure 103 extends in one direction, the same stress is exerted on the active area 101 in a large area, and the dislocation 104 is generated on a region of the active area 101. Current leakage and other undesirable characteristics are caused by the dislocation 104 in the active area 101. Thus, the dislocation adversely affects operational characteristics (e.g., a program operation, an erase operation and a read operation) of the flash memory device.

### SUMMARY OF THE INVENTION

Embodiments of the present invention disperse stress exerted on an active area through an isolation structure, thereby improving operational characteristics of a flash memory device.

The flash memory device according to an embodiment of the present invention comprises a semiconductor substrate including first active areas and isolation areas alternately arranged to be parallel to each other, and second active areas connecting the first active areas to each other. Isolation structures are formed on the isolation areas. Drain select lines, word lines, and source select lines are formed such that the drain select lines, the word lines and the source select lines intersect the first active areas. Junction areas are formed on the first active areas between a drain select line and an adjacent word line, between adjacent word lines, and between a source select line and an adjacent word line. Drains are formed on the first active areas between adjacent drain select lines. A common source is formed on the first active areas and the second active areas between adjacent source select lines.

In the embodiments of the present invention, it is desirable that each second active area has a width which is substantially the same as a width of each first active area or less than three times the width of each first active area. It is also desirable that a distance between the source select lines is substantially the same as a width of each second active area or less than ten times the width of each second active area.

The flash memory device according to another embodiment of the present invention includes first trenches formed on a semiconductor substrate between active areas defined in one direction. Second trenches are formed on the active areas and connect the first trenches to each other. Isolation structures are formed in the first trenches. Drain select lines, word lines, and source select lines are formed such that the drain select lines, the word lines, and the source select lines intersect the active areas. Junction areas are formed on the active areas between a drain select line and an adjacent word line, between adjacent word lines, and between a source select line and an adjacent word line. Drains are formed on the active areas between adjacent drain select lines. A common source is formed on side walls and bottom surfaces of the first trenches and the second trenches between adjacent source select lines.

In the above embodiment, it is preferred that each first trench has a width which is less than a distance between adjacent source select lines. It is desirable that each second trench has a width which is substantially the same as a width of the active area or less than three times the width of the active area. It is also desirable that a distance between the source select lines is substantially the same as a width of each second trench or less than ten times the width of each second trench.

A method of manufacturing the flash memory device according to an embodiment of the present invention includes providing a semiconductor substrate including first active areas and isolation areas alternately arranged to be parallel to each other, and second active areas connecting the first active areas to each other. A tunnel insulating layer, a charge storage layer, and an isolation mask are formed on the semiconductor substrate. The isolation mask, the charge storage layer, the tunnel insulating layer, and the semiconductor substrate are etched to form a trench on each isolation area. An isolation structure is formed on the trench of each isolation area. A dielectric layer, a conductive layer for a control gate, and a hard mask are sequentially formed on a structure that includes the isolation structure. The hard mask, the conductive layer for the control gate, the dielectric layer, and the charge storage layer are patterned to form drain select lines, word lines, and source select lines intersecting each first active area. Junction areas are formed on the first active areas through an ion implanting process. A common source is formed on the first active areas and the second active areas between adjacent source select lines.

In the above method, it is desirable that each second active area has a width which is substantially the same as a width of each first active area or less than three times the width of each first active area. It is also desirable that a distance between the source select lines is substantially the same as a width of the second active area or less than ten times the width of the second active area.

The method of manufacturing the flash memory device according to another embodiment of the present invention comprises forming a tunnel insulating layer, a charge storage layer, and an isolation mask on a semiconductor substrate. The isolation mask, the charge storage layer, the tunnel insulating layer, and the semiconductor substrate are etched to form first trenches on an isolation area and second trenches on a portion of an active area such that the first trenches are connected to each other. An isolation structure is formed in each of the first trenches and each of the second trenches. A dielectric layer, a conductive layer for a control gate, and a hard mask are formed sequentially on a structure including the isolation structure. The hard mask, the conductive layer for the control gate, the dielectric layer, and the charge storage layer are patterned to form drain select lines, word lines, and source select lines intersecting the active area. An interlayer insulating layer is formed on a structure that includes the word lines. A contact hole is formed on the interlayer insulating layer to expose a region between adjacent source select lines. The isolation structure is removed from an upper side of the second trench that is exposed through the contact hole. A common source is formed on side walls and bottom surfaces of the first trenches and the second trenches between adjacent source select lines.

In the above method, it is preferred that the second trench has a width which is substantially the same as a width of the active area or less than three times the width of the active area. It is also preferred that a distance between adjacent source select lines is substantially the same as a width of the second trench or less than ten times the width of the second trench. The method may further comprise performing an ion implanting process to form junction regions on the semiconductor substrate between adjacent drain select lines, between adjacent word lines, and between adjacent source select lines before forming the interlayer insulating layer. In addition, the method may further comprise forming spacers on side walls of the drain select lines, the word lines, and the source select lines before forming the interlayer insulating layer.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a layout showing an active area and an isolation area in a cell area of a conventional NAND flash memory device;

FIG. 2 is a photograph showing where a dislocation is generated in an active area of a semiconductor substrate;

FIG. 3 is a layout of a flash memory device according to an embodiment of the present invention;

FIG. 4A to FIG. 4C are sectional views taken along line A-A′ and line B-B′ in FIG. 3;

FIG. 5 is a layout of a flash memory device according to another embodiment of the present invention; and

FIG. 6A to FIG. 6F are sectional views taken along line A-A′ and line B-B′ in FIG. 5.

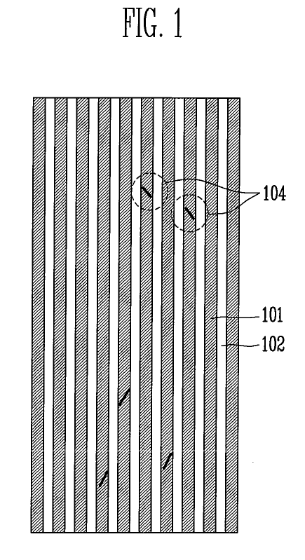

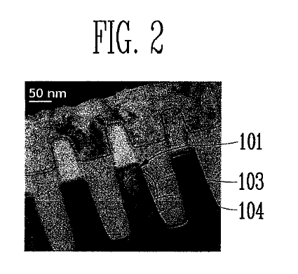

### DESCRIPTION OF SPECIFIC THE INVENTION

Embodiments of the present invention will be described in detail with reference to the accompanying drawings. However, the present invention is not limited to the embodiments disclosed below, but may be embodied in various configurations. The embodiments disclose an example of the present invention. Those skilled in the art will appreciate the complete scope of the present invention with reference to the accompanying claims.

In the below description, the expression of “there is one layer or the other layer on the semiconductor substrate” means that one layer or the other layer may directly contact the semiconductor substrate or a third layer may be disposed between the two layers. Also, in order to offer a better understanding of the description, a thickness and size of each layer are exaggeratingly illustrated in the drawings. Furthermore, the same reference numeral indicates the same element in the drawings.

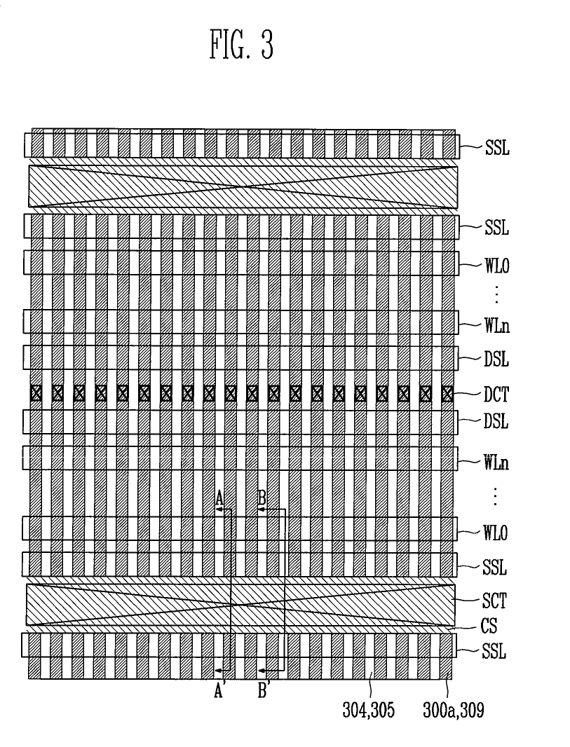

FIG. 3 is a layout of a flash memory device according to an embodiment of the present invention. A cell array of the NAND flash memory device comprises isolation areas 304 and active areas 300a. A trench or an isolation structure 305 is formed on each isolation area. The isolation areas 304 and the active areas 300a are alternately arranged to be parallel to each other. In general, the isolation areas and the active areas are arranged to be parallel to a direction of a bit line. Drain select lines DSL and source select lines SSL are formed such that the drain select lines and the source select lines intersect the active areas 300a. A plurality of word lines WL0 to WLn are formed between the drain select line DSL and the source select line SSL. A junction region is formed on each of the active areas 300a between adjacent select lines (DSL and SSL), between a word line and an adjacent select line, and between adjacent word lines. The junction regions formed between adjacent drain select lines DSL become drains, and drain contact plugs DCT are formed on the drains. The junction regions formed between adjacent source select lines SSL become a common source CS, and a source contact line SCT is formed on the common source CS.

The isolation structure is not formed between adjacent source select lines SSL. The junction regions are connected to each other between adjacent source select lines SSL. In other words, the active areas 300a are not interrupted by the source select lines SSL. Rather, the active areas 300a are connected to each other and extend lengthwise. Impurities are injected into the active areas 300a between adjacent source select lines SSL, so that the source select line SSL and the common source CS are formed parallel to each other. A width of the active area 300a between adjacent source select lines SSL is substantially the same as a width of the active area or larger than three times the width of the active area intersecting the select line DSL or SSL or a word line (for example WL0). A distance between adjacent source select lines SSL may be substantially the same as a width of the active area 300a or less than ten times the width of the active area 300a between adjacent source select lines SSL.

Accordingly, the isolation area 304 is interrupted at every region on which the common source CS is formed. Thus, stress exerted on the active areas 300a is dispersed by separating the isolating areas 304, thereby preventing dislocation from being generated in the active area 300a.

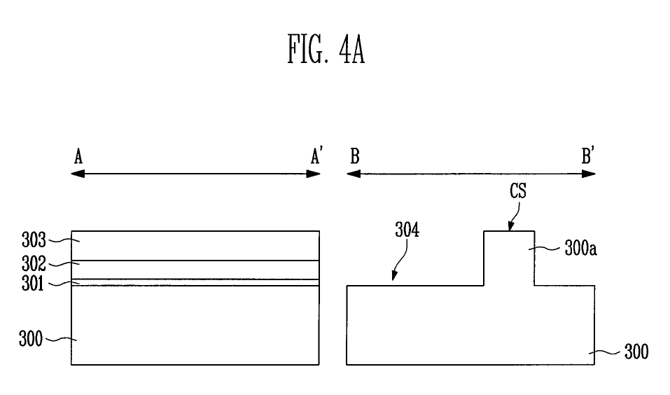

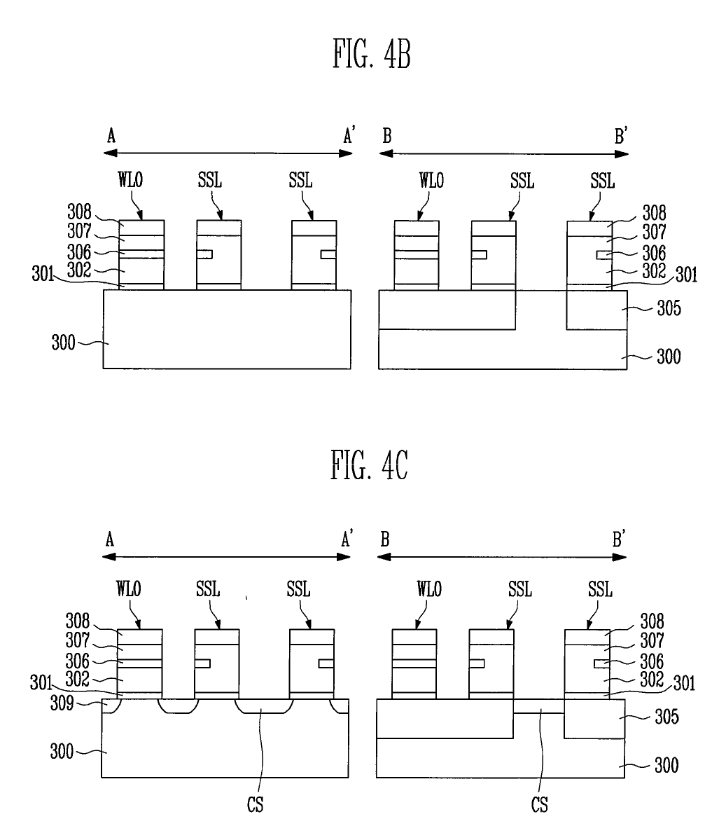

FIG. 4A to FIG. 4C are sectional views taken along line A-A′ and line B-B′ in FIG. 3.

Referring to FIG. 3 and FIG. 4A, a tunnel insulating layer 301, a charge storage layer 302 and an isolation mask 303 are sequentially formed on a semiconductor substrate 300. The isolation mask 303 is formed having a pattern through which an isolation area 304 is exposed. The isolation mask 303 may have a stack structure including a buffer oxide layer, a nitride layer and a reflection prevention layer. Subsequently, the charge storage layer 302, the tunnel insulating layer 301, and the semiconductor substrate 300 of the isolation area 304 are etched using an etching process where the isolation mask 303 is provided as an etching mask. A trench is formed in the isolation area 304, and an area on which the trench is not formed is identified as the active area 300a. The trenches 304 and the active areas 300a are alternately arranged to be parallel to each other. The active areas 300a are connected to each other in an area on which the common source CS is later formed. In other words, a trench is not formed in the area on which the common source CS is later formed. As a result of the structure described above, all the active areas 300a are connected to each other between adjacent source select lines SSL, and the trenches 304 are discontinuously formed by the connected active areas 300a.

Referring to FIG. 3 and FIG. 4B, a dielectric layer 306, a conductive layer 307 for the control gate, and a hard mask 308 are sequentially formed. The conductive layer 307 for the control gate, the dielectric layer 306, and the charge storage layer 302 are then etched through the etching process utilizing the hard mask 308. The drain select lines DSL, the source select lines SSL, and the word lines WL0 to WLn are thereby formed. The trench is not exposed between adjacent source select lines SSL; only the active area 300a is exposed.

The charge storage layer 302 and the conductive layer 307 for the control gate included in the drain select line DSL and the source select line SSL should be connected to each other. Accordingly, the dielectric layer on an area on which the select lines DSL and SSL are formed may be etched before forming the conductive layer 307 for the control gate. Thus, only a portion of the dielectric layer 306 remains on the select lines DSL and SSL, or the dielectric layer 306 is removed.

Referring to FIG. 3 and FIG. 4C, junction regions 309 are formed by performing an ion implanting process. The junction regions 309 are formed between adjacent select lines DSL and SSL and between adjacent word lines WL0 to WLn. The junction regions disposed between adjacent drain select lines DSL become the drains. The drains are isolated from each other by the isolation structure. The junction regions disposed between adjacent source select lines SSL become the common source CS. Since the junction region 309 is continuously connected between adjacent source select lines SSL, the common source CS is also continuously formed and is parallel to the source select lines SSL.

A conventional process is performed to form the source contact line SCT on the common source CS and to form the drain contact plug DCT on the drain between adjacent drain select lines DSL.

In the above structure, since the active areas 300a are connected to each other between adjacent source select lines SSL, stress exerted on the active areas can be dispersed when forming the isolation structure on a region between adjacent source select lines SSL.

FIG. 5 is a layout of a flash memory device according to another embodiment of the present invention. A cell array of the NAND flash memory device comprises isolation areas 604 and active areas 600a. A trench or an isolation structure 605 is formed on each isolation area. The isolation areas 604 and the active areas 600a are alternately arranged to be parallel to each other. The isolation areas 604 and the active areas 600a are parallel to a direction of a bit line. Drain select lines DSL and source select lines SSL are formed such that the drain select lines and the source select lines intersect the active areas 600a. A plurality of word lines WL0 to WLn are formed between the drain select line DSL and the source select line SSL. A junction region is formed on each of the active areas 300a between adjacent select lines DSL and SSL, between a word line and an adjacent select line, and between adjacent word lines. The junction regions formed between adjacent drain select lines DSL become drains, and drain contact plugs DCT are formed on the drains. The junction regions formed between adjacent source select lines SSL become a common source CS, and a source contact line SCT is formed on the common source CS.

FIG. 3 shows that the junction regions are connected to each other in the region on which the common source is formed. However, FIG. 5 shows that the trenches are connected to each other on a region on which the common source CS is formed (hereinafter, referred to as “common source region”), and the isolation structure 605 is formed in the trench. In other words, the isolation structure 605 is continuously formed lengthwise parallel to the source select line SSL and between adjacent source select lines SSL. The isolation structure formed on the common source region between adjacent source select lines SSL is removed, and a side wall and a bottom surface of the trench are exposed when the isolation structure is removed. The common source CS is formed on the exposed side wall and bottom surface of the trench through an ion implanting process. Consequently, as shown in FIG. 3, the common source CS is formed parallel to the source select lines SSL and between adjacent source select lines SSL. A width of the trench formed parallel to and between adjacent source select lines SSL is substantially the same as the width of the active area intersecting the select line (DSL or SSL) or the word line. Alternatively, the width of the trench formed parallel to and between adjacent source select lines SSL is larger than three times the width of the active area intersecting the select line (DSL or SSL) or the word line. It is desirable that a distance between adjacent source select lines SSL is larger than a width of the trench formed between adjacent source select lines SSL. It is also desirable that the distance between adjacent source select lines SSL is less than ten times the width of the trench formed between adjacent source select lines SSL.

As described above, the isolation structure 605 formed between adjacent source select lines SSL is removed. Accordingly, stress exerted on the active areas 600a is dispersed when depositing insulative material for forming the isolation structure 605. Thus, it is possible to prevent dislocation from being generated in the active area 600a.

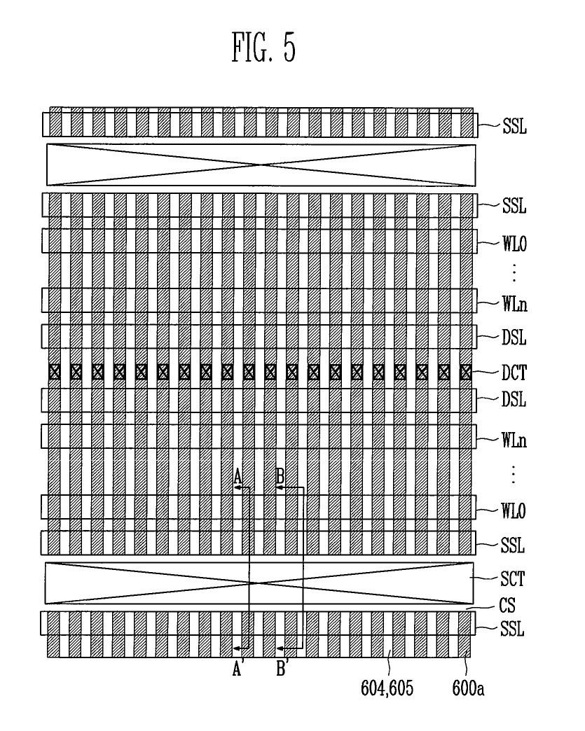

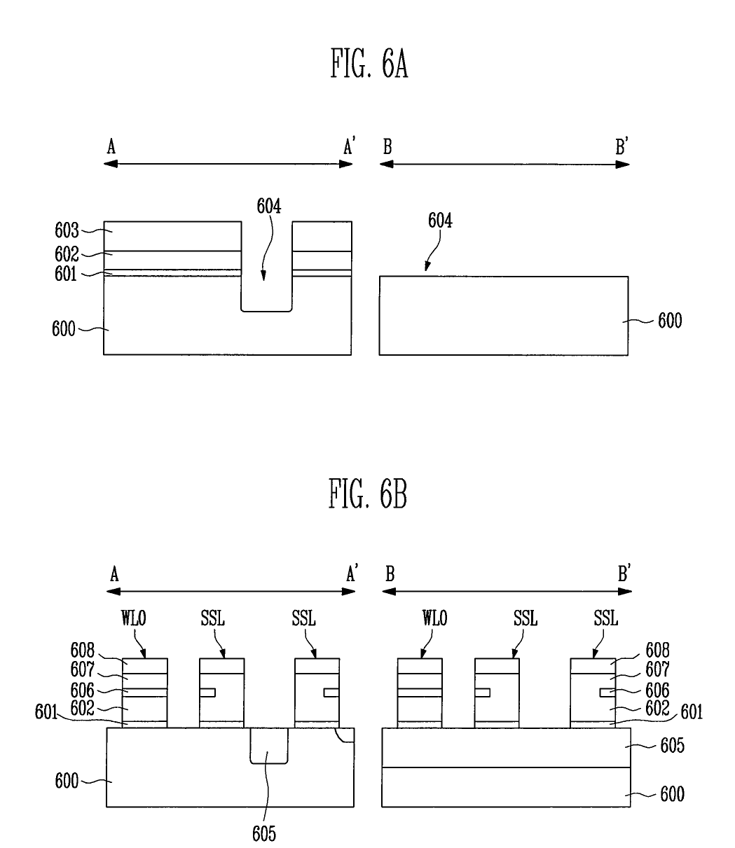

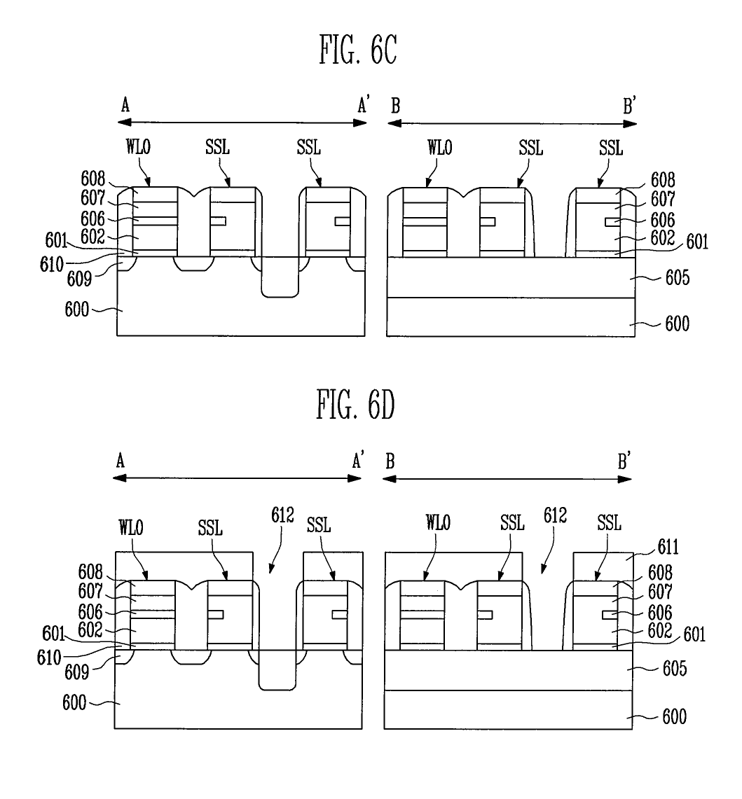

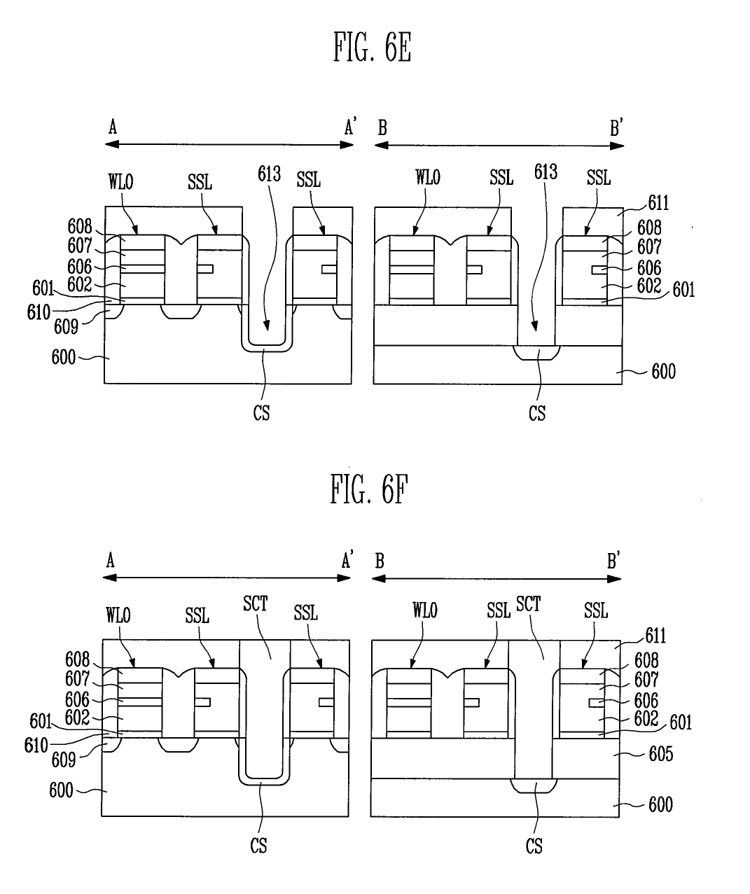

FIG. 6A to FIG. 6F are sectional views taken along the A-A′ and the B-B′ in FIG. 5.

Referring to FIG. 5 and FIG. 6A, a tunnel insulating layer 601, a charge storage layer 602, and an isolation mask 6603 are sequentially formed on a semiconductor substrate 600. The isolation mask 603 is formed into a pattern through which the isolation area is exposed. The isolation mask 603 may have a stack structure including a buffer oxide layer, a nitride layer, and a reflection prevention layer. The charge storage layer 602, the tunnel insulating layer 601, and the semiconductor substrate 600 of the isolation area are etched through an etching process using the isolation mask 603 as an etching mask. A trench is formed in the isolation area 604. An area on which the trench is not formed is identified as the active area 600a. The trenches 604 and the active areas 600a are alternately arranged to be parallel to each other. The trenches 604 are connected to each other in the common source region. In other words, the trench is continuously formed lengthwise between adjacent source select lines SSL. The active areas 600a are discontinuously formed by the trench 604 that is formed lengthwise between adjacent source select lines SSL, as described above. Although not shown in the drawings, it is preferable that a width of the trench 604 is smaller than that of the source select line SSL (i.e., a width of the common source region). FIG. 6A depicts that the trench 604 has a narrow width.

Referring to FIG. 5 and FIG. 6B, a dielectric layer 606, a conductive layer 607 for the control gate, and a hard mask 608 are sequentially formed. The conductive layer 607 for the control gate, the dielectric layer 606, and the charge storage layer 602 are then etched through an etching process utilizing the hard mask 608. The drain select lines DSL, the source select lines SSL and the word lines WL0 to WLn are thereby formed. The isolation structure 605 is exposed between adjacent source select lines SSL. If the trench 604 is narrower than a distance between adjacent source select lines SSL, as shown in FIG. 6A, a portion of the semiconductor substrate 600 is exposed between the source select lines SSL.

The charge storage layer 602 and the conductive layer 607 for the control gate included in the drain select line DSL and the source select line SSL should be connected to each other. Accordingly, the dielectric layer on an area on which the select lines DSL and SSL are formed may be etched before forming the conductive layer 607 for the control gate. Thus, only a portion of the dielectric layer 606 remains on the select lines DSL and SSL, or the dielectric layer 606 is removed.

Referring to FIG. 5 and FIG. 6C, junction regions 609 are formed by performing an ion implanting process. The junction regions 609 are formed between adjacent select lines DSL and SSL and between adjacent word lines WL0 to WLn. The junction regions disposed between adjacent drain select lines DSL become the drains, and the drains are isolated from each other by the isolation structure. The junction regions 609 are also formed on the semiconductor substrate 600 between the source select line SSL and the isolation structure 605, and the junction regions 609 formed between the source select line SSL and the isolation structure 605 become a portion of the common source CS.

Spacers 610 are formed on side walls of the select lines DSL and SSL and the word lines WL0 to WLn. A space between the word lines WL0 to WLn is filled with the spacer 610 when the spacer is formed on the side walls between the select lines DSL and SSL. The spacer 610 may be overlapped with the isolation structure 605; however, it is preferable to form the spacer without overlapping the spacer with the isolation structure 605.

Referring to FIG. 5 and FIG. 6D, an interlayer insulating layer 611 is formed on a structure. A contact hole 612 is formed by etching a portion of the interlayer insulating layer 611 so as to expose a region between adjacent source select lines SSL. Thus, the isolation structure 605 is exposed. Since an alignment error is generated when the interlayer insulating layer 611 is etched to form the contact hole 612 and side walls of the source select lines SSL may be exposed due to the alignment error, it is preferable that the spacers 610 to be formed on the side walls of the source select lines SSL are formed utilizing a substance having an etching selection ratio which differs from that of the substance constituting the interlayer insulating layer 611.

Referring to FIG. 5 and FIG. 6E, the isolation structure 605 that is exposed through the contact hole 612 is removed, thereby forming a trench 613. The isolation structure 605 between the source select lines SSL is removed, and a side wall and a bottom surface of the trench 613 are exposed. Pentavalent impurities such as boron (B) or arsenic (As) are implanted into a side wall and a bottom surface of the trench 613 through an ion implanting process to form the common source CS. Although the impurities are implanted perpendicularly so that the common source CS is formed on only the bottom surface of the trench 613, the above structure does not become an issue since the trench 613 will be filled with conductive material in a subsequent process to form the contact line. It is preferred that the impurities are implanted on the bottom surface as well as the side walls of the trench 613. Accordingly, in order to implant the impurities on the side walls of the trench 613, the impurities are implanted through an inclined ion implanting process. In the isolation area of the region between the source select lines SSL, the isolation structure 605 on the side walls of the trench 613 is exposed and the semiconductor substrate 600 is exposed through the bottom surface. Thus, the common source CS is formed on the bottom surface of the trench 613. Similar to the source select line SSL, the common source CS is continuously formed lengthwise between adjacent source select lines SSL.

Referring to FIG. 5 and FIG. 6F, the trench 613 is filled with a conductive substance to form the source contact line SCT on the common source CS. A conventional process is performed to form the drain contact plug DCT on each drain between adjacent drain select lines DSL.

As described above, the present invention disperses stress exerted on the active area through the isolation structure, thereby improving the operational characteristics of the flash memory device.

Although the technical spirit of the present invention has been concretely described in connection with the preferred embodiment, the scope of the present invention is not limited by the specific embodiments but should be construed by the appended claims. Further, it should be understood by those skilled in the art that various changes and modifications can be made thereto without departing from the scope of the present invention.

What is claimed is:

1. A flash memory device, comprising;
a semiconductor substrate including first active areas and isolation areas alternately arranged to be parallel to each other, and second active areas connecting the first active areas to each other;
isolation structures formed on the isolation areas;
drain select lines, word lines, and source select lines formed such that the drain select lines, the word lines, and the source select lines intersect the first active areas, wherein a plurality of the word lines are formed between one drain select line and one source select line;
junction areas formed on the first active areas between a drain select line and an adjacent word line, between adjacent word lines, and between a source select line and an adjacent word line;
drains formed on the first active areas between adjacent drain select lines; and
a common source formed on the first active areas and the second active areas between adjacent source select lines.

2. The flash memory device as claimed in claim 1, wherein each second active area has a width which is one of: substantially the same as a width of each first active area or less than three times the width of each first active area.

3. The flash memory device as claimed in claim 1, wherein a distance between the source select lines is one of: substantially the same as a width of each second active area or less than ten times the width of each second active area.

4. A flash memory device, comprising;
first trenches formed on a semiconductor substrate between active areas, wherein the first trenches are formed in one direction;
second trenches formed on the active areas, wherein the second trenches connect the first trenches to each other;
isolation structures formed in the first trenches;
drain select lines, word lines and source select lines formed such that the drain select lines, the word lines and the source select lines intersect the active areas, wherein a plurality of the word lines are formed between one drain select line and one source select line;
junction areas formed on the active areas between a drain select line and an adjacent word line, between adjacent word lines, and between a source select line and an adjacent word line;
drains formed on the active areas between adjacent drain select lines; and
a common source formed on side walls and bottom surfaces of the first trenches and the second trenches formed between adjacent source select lines.

5. The flash memory device as claimed in claim 4, wherein each second trench has a width which is less than a distance between adjacent source select lines.

6. The flash memory device as claimed in claim 4, wherein each second trench has a width which is one of: substantially the same as a width of each active area or less than three times the width of each active area.

7. The flash memory device as claimed in claim 4, wherein a distance between adjacent source select lines is larger than one of: a width of each second trench or less than ten times the width of each second trench.

8. A method of manufacturing a flash memory device, the method comprising:
providing a semiconductor substrate including first active areas and isolation areas alternately arranged to be parallel to each other, and second active areas connecting the first active areas to each other;
forming a tunnel insulating layer, a charge storage layer and an isolation mask on the semiconductor substrate;
etching the isolation mask, the charge storage layer, the tunnel insulating layer and the semiconductor substrate to form a trench on the isolation area;
forming an isolation structure on the trench of the isolation area;
forming a dielectric layer, a conductive layer for a control gate, and a hard mask on a structure that includes the isolation structure;
patterning the hard mask, the conductive layer for the control gate, the dielectric layer, and the charge storage layer to form drain select lines, word lines and source select lines intersecting the first active area;
forming junction areas on the first active areas through an ion implanting process; and
forming a common source on the first active areas and the second active areas between adjacent source select lines.

9. The method of manufacturing the flash memory device as claimed in claim 8, wherein the second active area has a width which is one of: substantially the same as a width of each first active area or less than three times the width of each first active area.

10. The method of manufacturing the flash memory device as claimed in claim 8, wherein a distance between adjacent source select lines is one of: substantially the same as a width of each second active area or less than ten times the width of each second active area.

11. A method of manufacturing a flash memory device, the method comprising:
forming a tunnel insulating layer, a charge storage layer, and an isolation mask on a semiconductor substrate;
etching the isolation mask, the charge storage layer, the tunnel insulating layer, and the semiconductor substrate to form first trenches on the isolation area and second trenches on a portion of an active area such that the first trenches are connected to each other;
forming an isolation structure in the first trenches and the second trenches;
forming a dielectric layer, a conductive layer for a control gate, and a hard mask on a structure that includes the isolation structure;
patterning the hard mask, the conductive layer for the control gate, the dielectric layer, and the charge storage layer to form drain select lines, word lines, and source select lines that intersect the active area, wherein a plurality of the word lines are formed between one drain select line and one source select line; and
forming an interlayer insulating layer on a structure that includes the word lines;
forming a contact hole on the interlayer insulating layer to expose a region between adjacent source select lines;
removing the isolation structure on an upper side of the second trench that is exposed through the contact hole; and
forming a common source on side walls and bottom surfaces of the first trench and the second trench between the adjacent source select lines.

12. The method of manufacturing the flash memory device as claimed in claim 11, wherein the second trench has a width which is one of: substantially the same as a width of the active area or less than three times the width of the active area.

13. The method of manufacturing the flash memory device as claimed in claim 11, wherein a distance between adjacent source select lines is one of: substantially the same as a width of each second trench or less than ten times the width of each second trench.

14. The method of manufacturing the flash memory device as claimed in claim 11, further comprising performing an ion implanting process to form junction regions on the semiconductor substrate between adjacent drain select lines, between adjacent word lines, and between adjacent source select lines before forming the interlayer insulating layer.

15. The method of manufacturing the flash memory device as claimed in claim 11, further comprising forming spacers on side walls of the drain select lines, the word lines and the source select lines before forming the interlayer insulating layer.
